(19) United States
(12) Patent Application Publication
(10) Pub. No.: US 2003/0146489 A1
(43) Pub. Date: Aug. 7, 2003

(54) Semiconductor device and method of manufacturing the same

(75) Inventor: Satoshi Shimizu, Tokyo (JP)

Correspondence Address: McDermott, Will & Emery, 600 13th Street, N.W., Washington, DC, 20005-3096, US

(73) Assignee: MITSUBISHI DENKI KABUSHIKI KAISHA, Tokyo (JP)

(21) Appl. No.: 10/366,563

(22) Filed: Feb. 14, 2003

Related U.S. Application Data
(62) Division of application No. 09/289,714, filed on Apr. 12, 1999.

(30) Foreign Application Priority Data
Dec. 8, 1998 (JP) HEI 10-348510

(51) Int. Cl. H01L 29/04; H01L 29/00; H01L 31/036

(52) U.S. Cl. 257/521; 257/627; 257/510; 257/513; 257/527

(57) ABSTRACT

A semiconductor device provided with an isolation oxide film formed by a trench isolation technique is described. The device prevents the development of crystal defects from the corners of a trench and secures stable operating characteristics. The semiconductor device is provided with an isolation oxide film formed so that boundaries between an active region and the isolation oxide film extend in a direction inclined at an angle in the range of 45°±10° to the cleavage plane of a silicon substrate. The isolation oxide film has a interior wall oxide film of a thickness in the range of 50 Å to 1000 Å coating the side walls and the bottom wall of a trench, and a filling oxide film filling up the trench coated with the interior wall oxide film. The edges of the active region contiguous to the isolation oxide film are rounded properly.

### BACKGROUND OF THE INVENTION

1. Field of the Invention

The present invention relates to a semiconductor device and a method of manufacturing the same. More particularly, the present invention relates to a semiconductor device provided with an isolation oxide film formed by a trench isolation technique, and a method of manufacturing the same.

2. Description of the Background Art

It has been known a semiconductor device provided with an isolation oxide film formed by a trench isolation technique. FIG. 18 is a plan view of a substrate 10 included in a related art semiconductor device. In FIG. 18, two arrows crossing perpendicular to each other indicate the direction of the cleavage plane of the substrate 10, i.e., a plane along which the single-crystal silicon substrate 10 may easily be split due to the property of silicon crystal.

An isolation oxide film 12 is formed on a surface of the substrate 10. The isolation oxide film 12 divides the surface of the substrate 10 into a plurality of active regions 14. Generally, the isolation oxide film 12 is designed so that boundaries between the active regions 14 and the isolation oxide film 12 are formed in a direction perpendicular or parallel to the cleavage plane of the substrate 10 as shown in FIG. 18. The isolation oxide film 12 thus formed (1) facilitates the handling of design data on a CAD system, (2) facilitates the sectional analysis of the substrate 10 and (3) facilitates cutting out chips along dicing lines.

A related art method of forming the isolation oxide film 12 on the substrate 10 by a trench isolation technique will be described with reference to FIGS. 19 to 23 showing a region surrounded by broken lines in FIG. 18 in perspective views taken in the direction of the arrow A.

When forming the isolation oxide film 12, a silicon oxide film 16 and a silicon nitride film 18 are formed in that order on the substrate 10. Then, a resist film, not shown, having an opening corresponding to the isolation oxide film 12 is formed by a photolithography process. Desired parts of the silicon nitride film 18, the silicon oxide film 16 and the substrate 10 are etched sequentially by using the resist film as a mask to form trenches 20 in the substrate 10 as shown in FIG. 19. The related art method forms the trenches 20 along the cleavage plane of the substrate 10. Therefore, the cleavage plane of the substrate 10 appear on the side walls of the trench 20, and a crystal face of properties different from those of the cleavage face appears on the bottom wall of the trench 20.

Then, a thermal oxidation process is carried out to form an oxide film 22 (hereinafter referred to as an “interior wall oxide film 22”) on the walls of the trench 20. Then, a filling oxide film 24 is deposited by a CVD (Chemical Vapor Deposition) process on the silicon nitride film 18 and a space in the trench 20 coated with the interior wall oxide film 22 (FIG. 20).

The filling oxide film 24 deposited on the silicon nitride film 18 is removed by a CMP (Chemical Mechanical Polishing) process. During the CMP process, the silicon nitride film 18 serves as a stopper film for stopping excessive CMP. Consequently, the filling oxide film 24 remains only in the trench 20 (FIG. 21).

The silicon nitride film 18 is removed by using hot phosphoric acid after the completion of the CMP process (FIG. 22). Then, the silicon oxide film 16 remaining inactive regions, i.e., regions surrounded by the trench 20, is removed together with unnecessary parts of the filling oxide film 24, i.e., top and edge parts of the remaining filling oxide film 24, by using hydrofluoric acid. Consequently, the isolation oxide film 12 isolating the active regions of the substrate 10 from each other is formed (FIG. 23).

As mentioned above, the trench 20 is formed by etching, and then the interior wall oxide film 22 is formed so as to coat the walls of the trench 20 when forming the isolation oxide film 12. In the etching process for forming the trench 20, surfaces of the substrate 10 exposed to the trench 20 are damaged. If the interior wall oxide film 22 is formed by thermal oxidation, the damage surfaces are oxidized so as to change to oxide films as well as being heat-treated, whereby the damaged surfaces can be removed from the substrate 10.

In the formation process of the isolation oxide film 12, the filling oxide film 24 is deposited in the trench 20 by the CVD process. The interior wall oxide film 22 protects the silicon substrate 10 during the CVD process. Accordingly, the silicon substrate 10 can effectively be protected by the interior wall oxide film 22 from the damaging effect during the CVD process.

During an etching process using hydrofluoric acid, the etching rate of the interior wall oxide film 22 formed by the thermal oxidation is lower than that of the filling oxide film 24. Therefore, forming the interior wall oxide film 22 covering the surfaces of the trench 20 prevents forming recesses in the boundaries between the active regions 14 of the substrate 10 and the isolation oxide film 12. In some cases, a gate electrode of a transistor is formed on the substrate 10 so as to extend across the isolation oxide film 12. If a recess is formed in the boundary between the active region 14 and the isolation oxide film 12, the gate electrode is formed so as to conform to the recess.

When a voltage is applied to the gate electrode conforming to the recess formed in the isolation oxide film 12, an electric field generated in an active region 14 tends to concentrate at the end portion of the region 14, i.e., a peripheral portion contiguous to the recess. The active region 14 underlying the gate electrode serves as a channel of the transistor. Accordingly, an electric field tends to concentrate in an end of the channel when the gate electrode is formed so as to conform to the recess of the isolation oxide film 12. Under such circumstances, there arises an inverse narrow channel effect, i.e., a phenomenon that the threshold voltage of the transistor decreases with the reduction of the width of the channel. As mentioned above, formation of recesses in the isolation oxide film 12 can effectively be prevented by the interior wall oxide film 22. Accordingly, the interior wall oxide film 22 is capable of suppressing the occurrence of inverse narrow channel effect in the transistor.

As mentioned above, different crystal faces appear on the side walls and the bottom walls of the trench 20, respectively, when the isolation oxide film is formed by the related art method. Therefore, the part of the interior wall oxide film 22 covering the side walls of the trench 20 and the part of the same covering the bottom wall of the trench 20 are formed at different rate when the interior wall oxide film 22 is grown by thermal oxidation Consequently, the related art method forms the interior wall oxide film 22 having different thicknesses on the side walls and the bottom wall of the trench 20, respectively.

FIG. 24 is a sectional view of a peripheral part of the isolation oxide film 12 of the substrate 10. More concretely, the interior wall oxide film 22 having on the side walls a thickness greater than that on the bottom wall is formed in the trench as shown in FIG. 24. When the thickness of the interior wall oxide film 22 is different on the side walls and on the bottom wall, stress is apt to be concentrated on the corners of the trench 20, i.e., boundaries between the side walls and the bottom wall.

The corners of the trench 20 are simultaneously oxidized from both sides of the side walls and the bottom wall during the forming process of the interior wall oxide film 22 through use of thermal oxidation. Therefore, stresses greater than those induced in parts of the trench 20 other than the corners of the trench 20 tend to be induced in the corners of the trench 20 during the forming process of the interior wall oxide film 22.

In the related art structure, the corners of the trench 20 extend along the cleavage plane of the substrate 10, i.e., along a direction in which the substrate 10 tends to be split. Accordingly, the related art structure tends to form crystal defects 26 extending from the corners of the trench 20 in the substrate 10 as shown in FIG. 24. If such crystal defects 26 are formed, there arise problems such that junction leakage current in the circuit increases or punch through between the opposite sides of the isolation oxide film 12 is apt to occur. Consequently, the semiconductor device malfunctions or the power consumption of the semiconductor device increases.

### SUMMARY OF THE INVENTION

The present invention has been conceived to solve the previously-mentioned problems, and a general object of the present invention is to provide a novel and useful semiconductor device and method of manufacturing the same.

A more specific object of the present invention is to provide a semiconductor device capable of preventing the development of crystal defects from the corners of a trench and having stable operating characteristics.

The above object of the present invention is achieved by a semiconductor device described below. The device includes an isolation oxide film formed so that boundaries between the isolation oxide film and active regions extend in a direction at an angle in the range of 45°±10° to the cleavage plane of a silicon substrate. The isolation oxide film has an interior wall oxide film of a thickness in the range of 50 Å to 1000 Å covering side walls and bottom walls of trenches, and a filling oxide film filling up the trenches coated with the interior wall oxide film.

A second object of the present invention is to provide a method of manufacturing a semiconductor device having the foregoing characteristics.

The above object of the present invention is achieved by a method of manufacturing a semiconductor device comprising the steps described below. The method includes a step of forming a trench in a silicon substrate so that the boundary between an active region and the trench extends in a direction at an angle in the range of 45°±10° to the cleavage plane of the silicon substrate. The method also includes a step of subjecting the silicon substrate to thermal oxidation to form an interior wall oxide film of a thickness in the range of 50 Å to 1000 Å on side walls of the trench. The method further includes a step of forming an isolation oxide film by filling up the trench defined by walls coated with the interior wall oxide film with a filling oxide film.

Other objects and further features of the present invention will be apparent from the following detailed description when read in conjunction with the accompanying drawings.

### BRIEF DESCRIPTION OF THE DRAWINGS

FIG. 1 is a plane view of a substrate included in a semiconductor device according to a first or second embodiment of the present invention;

FIGS. 2 through 6 are perspective views for describing a manufacturing method of the semiconductor device according to the first embodiment;

FIG. 7 is a sectional view showing an isolation oxide film provided in the semiconductor device according to the first embodiment;

FIG. 8A is a sectional view showing a trench of before thermal oxidation included in the semiconductor device according to the first embodiment;

FIG. 8B is a sectional view showing a trench of after thermal oxidation included in a semiconductor device which is compared with the device according to the first embodiment;

FIG. 8C is a sectional view showing the trench of after thermal oxidation included in the semiconductor device according to the first embodiment;

FIG. 9 and FIGS. 11 through 14 are perspective views for describing a manufacturing method of the semiconductor device according to the second embodiment;

FIG. 10A is a sectional view showing a trench of before thermal oxidation included in the semiconductor device according to the second embodiment;

FIG. 10B is a sectional view showing a trench of after thermal oxidation included in a semiconductor device which is compared with the device according to the second embodiment;

FIG. 10C is a sectional view showing the trench of after thermal oxidation included in the semiconductor device according to the second embodiment;

FIG. 15 is a plane view of a substrate included in a semiconductor device according to a third embodiment of the present invention;

FIGS. 16 and 17 are sectional views for describing parts in which stress is induced during a formation process of an isolation oxide film;

FIG. 18 is a plane view of a substrate included in a related art semiconductor device;

FIGS. 19 through 23 are sectional views for describing a method of manufacturing the related art semiconductor device; and

FIG. 24 is a sectional view showing an isolation oxide film included in the related art semiconductor device.

### DESCRIPTION OF THE PREFERRED EMBODIMENTS

In the following, principles and embodiments of the present invention will be described with reference to the accompanying drawings. In the drawings the same parts are designated by the same reference characters and the duplicate description thereof will be omitted.

### First Embodiment

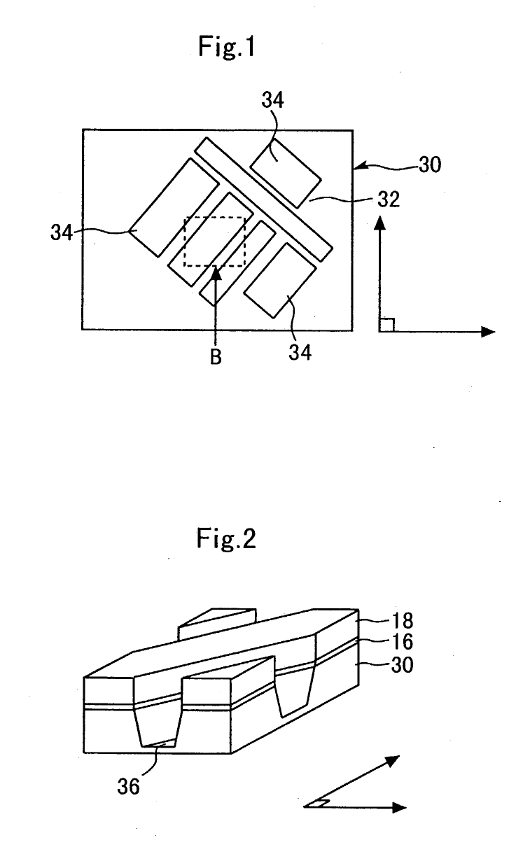

FIG. 1 is a plane view of a substrate 30 included in a semiconductor device in a first embodiment according to the present invention. In FIG. 1, two arrows running perpendicular to each other indicate the direction of the cleavage plane of the substrate 30, i.e., a plane along which the single-crystal silicon substrate 30 may easily be split due to the property of the silicon crystal.

An isolation oxide film 32 is formed on a surface of the substrate 30. The isolation oxide film 32 divides the surface of the substrate 30 into a plurality of active regions 34. In this embodiment, the isolation oxide film 32 is designed so that boundaries between the isolation oxide film 32 and the active regions 34 are inclined to the cleavage plane of the substrate 30 as shown in FIG. 1. More specifically, the isolation oxide film 32 is designed so that the boundaries between the isolation oxide film 32 and the active regions 34 are inclined at an angle in the range of 45°±10° to the direction of the cleavage plane of the substrate 30.

A method of forming the isolation oxide film 32 on the substrate 30 by a trench isolation technique will be described with reference to FIGS. 2 to 8.

FIGS. 2 to 6 are perspective views of a region surrounded by broken lines in FIG. 1 taken in the direction of the arrow B.

When forming the isolation oxide film 32, a silicon oxide film 16 and a silicon nitride film 18 are formed in that order on the substrate 30. Then, a resist film, not shown, having an opening at a region corresponding to the isolation oxide film 32 is formed by a photolithography process. Predetermined parts of the silicon nitride film 18, the silicon oxide film 16 and the substrate 30 are etched sequentially by using the resist film as a mask to form trenches 36 in the substrate 30 (see FIG. 2). A semiconductor device manufacturing method in the first embodiment forms the trenches 36 so as to extend along a predetermined direction inclined at an angle in the range of 45°±10° to the cleavage plane of the substrate 30. Therefore, crystal faces of properties different from those of the cleavage face of the substrate 30 appear on the side walls and the bottom wall of the trench 36.

Then, a thermal oxidation process is carried out to form an interior wall oxide film 38 on the walls of the trench 36. The side walls of the trench 36 are inclined at an inclination angle in the range of 60° to 90° to the surface of the substrate 30 so that the width of the trench 36 decreases toward the bottom of the trench 36. Process conditions for the thermal oxidation process are determined so that the interior wall oxide film 38 may be formed in a thickness corresponding to the inclination angle of the side walls. In this embodiment, the thickness of the interior wall oxide film 38 is in the range of 50 Å to 1000 Å, and the thickness is greater for the greater inclination angle of the side walls. More specifically, the process conditions are determined so that the thickness is 50 Å when the inclination angle of the side walls is 60°, the thickness is 1000 Å when the inclination angle of the side walls is 90°, and the thickness is set at a proper value in the range of 50 Å to 1000 Å when the inclination angle of the side walls is an angle in the range of 60° to 90°.

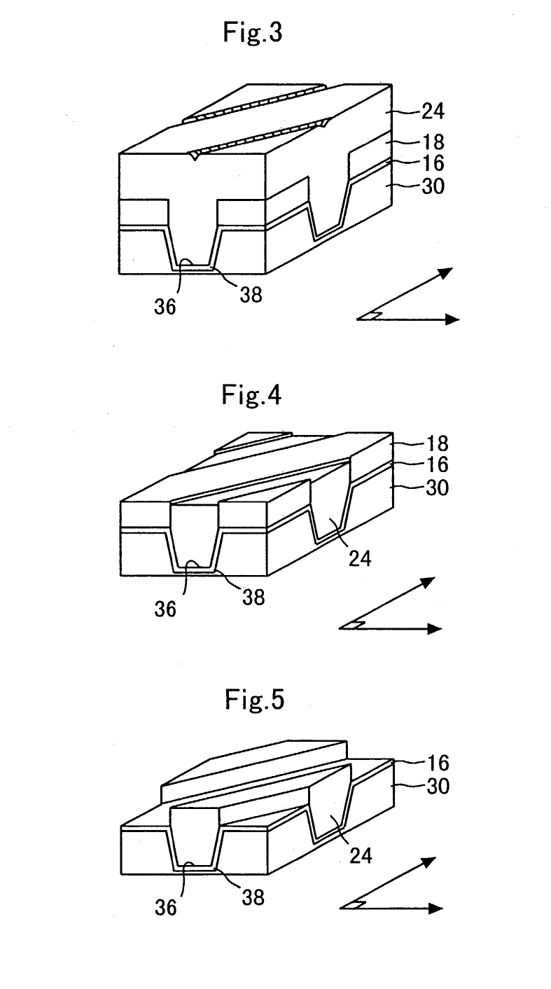

After the interior wall oxide film 38 has been formed, a filling oxide film 24 is deposited by a CVD process over the silicon nitride film 18 and in the trench 36 coated with the interior wall oxide film 38 (see FIG. 3).

The filling oxide film 24 deposited over the silicon nitride film 18 is removed by a CMP process. During the CMP process, the silicon nitride film 18 serves as a stopper film for stopping excessive CMP. Consequently, the filling oxide film 24 is deposited only in the trench 36 (see FIG. 4).

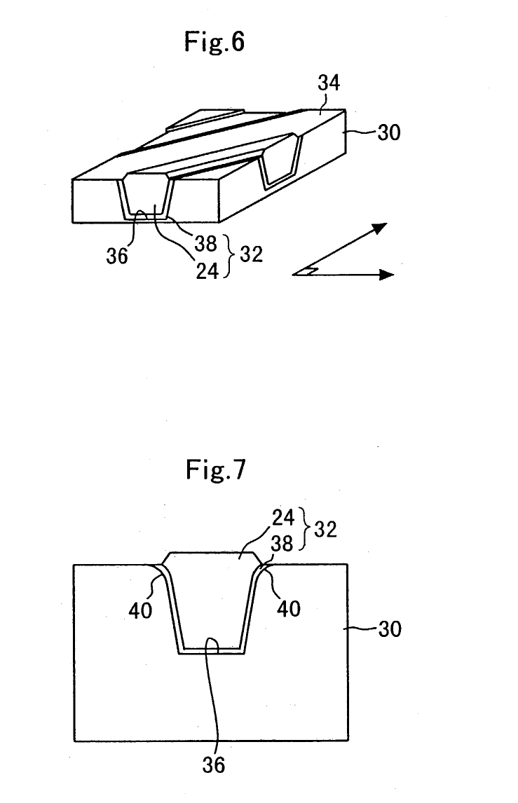

The silicon nitride film 18 is removed by using hot phosphoric acid after the completion of the CMP process (see FIG. 5). Then, the silicon oxide film 16 remaining in the active regions of the substrate 30, i.e., regions surrounded by the trench 36, is removed together with unnecessary parts of the filling oxide film 24, i.e., upper and edge parts of the remaining filling oxide film 24, by using hydrofluoric acid. Consequently, the isolation oxide film 32 isolating the active regions 34 of the substrate 30 from each other is formed (FIG. 6).

FIG. 7 is a sectional view of a part of the substrate 30 including the isolation oxide film 32 formed by the semiconductor device manufacturing method in the first embodiment. As mentioned above, crystal face of properties different from those of the cleavage face appear in both of the side walls and the bottom wall of the trench 36 in this embodiment. Therefore, during thermal oxidation for forming the interior wall oxide film 38, the interior wall oxide film 38 is formed at substantially the same rate on the side walls and the bottom wall of the trench 36. Consequently, the semiconductor device manufacturing method in the first embodiment forms the interior wall oxide film 38 having the same thickness on the side walls and the bottom wall of the trench 36.

When manufacturing the semiconductor device, oxidation processes for gate oxidation and gate side wall oxidation or the like, or heat-treatment processes for annealing to activate implanted ions, reflowing an interlayer insulating film and annealing to repair damage are carried out after forming the isolation oxide film 32. When the interior wall oxide film 38 is formed in the same thickness on the side walls and the bottom wall, stress which will be induced in the substrate 30 through the oxidation process or the heat-treatment process is suppressed lower than that will be induced in the same when the interior wall oxide film 38 is formed in different thicknesses on the side walls and the bottom wall, respectively.

Since the corners of the trench 36 extend obliquely to the cleavage plane of the substrate 30, the stress withstand ability of the corners is superior to the case in which corners of the trench 36 is formed along the cleavage plane. Therefore, the structure in this embodiment suppresses the development of crystal defects from the corners of the trench 36.

The semiconductor device manufacturing method in this embodiment is capable of forming satisfactory round rim 40 in the edges of the active regions 34 of the substrate 30 (boundaries between the isolation oxide film 32 and the active regions 34), limiting the thickness of the interior wall oxide film 38, particularly, the thickness of the interior wall oxide film 38 formed on the side walls to a value in the range of about 50 Å to about 1000 Å. That is, when the thermal oxidation is carried out under the condition in which the interior wall oxide film 38 is imparted with the aforementioned predetermined thickness in the manufacturing method in this embodiment, a satisfactory round edges 40 are formed in the edge of the active regions 34 while the thickness of the side walls of the interior wall oxide film 38 is sufficiently suppressed.

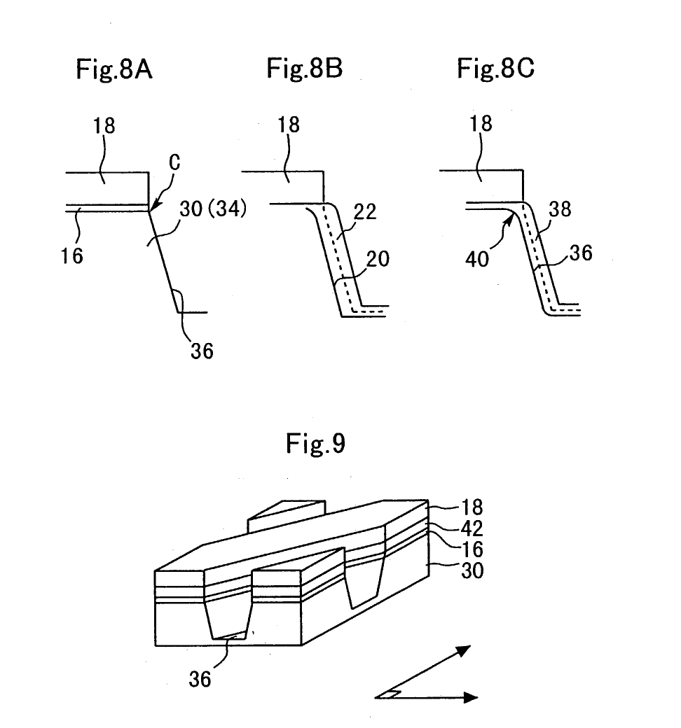

FIGS. 8A to 8C are sectional views of assistance in explaining the relation between the round edge 40 of the active region 34 and the thickness of the interior wall oxide film 38 on the side walls. FIG. 8A is a sectional view of a part of the substrate 30 including the trench 36 before thermal oxidation. The shape of the round edge 40 of the active region 34 of the substrate 30 is dependent on the amount of lateral retraction of the silicon region of the substrate 30 (hereinafter referred to as an “amount of inward oxide growth”) due to oxidation of the rim of the trench 36 (edge C in FIG. 8A) and the amount of lateral extension of the interior wall of the trench 36 due to oxidation (hereinafter referred to as “an amount of outward oxide growth”).

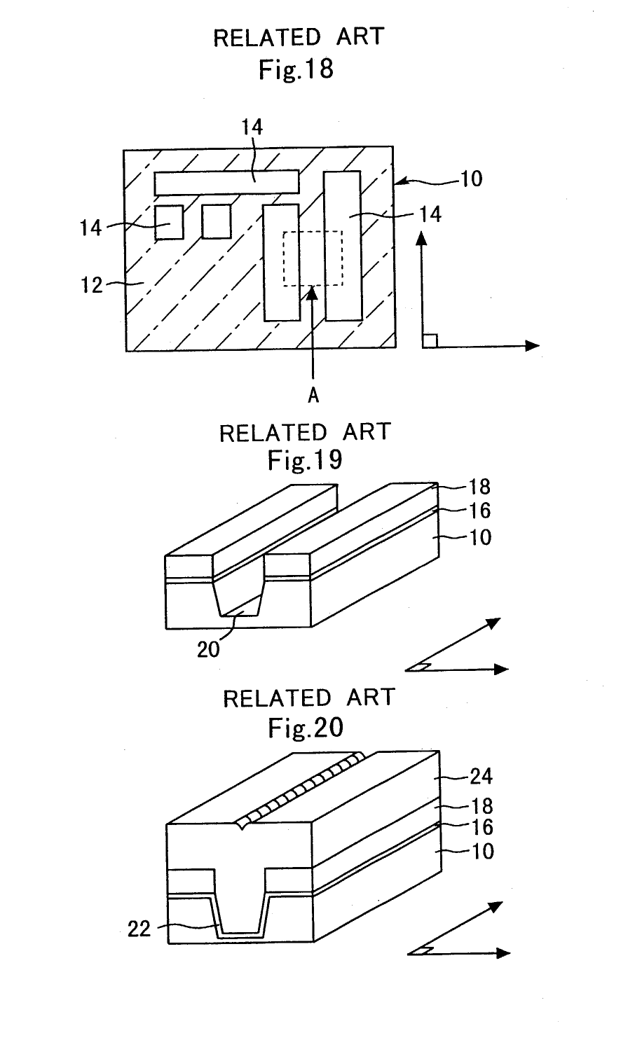

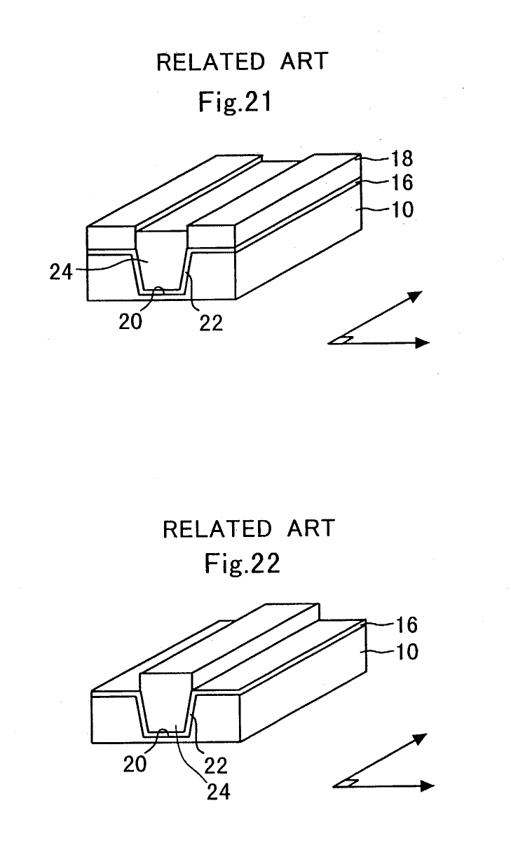

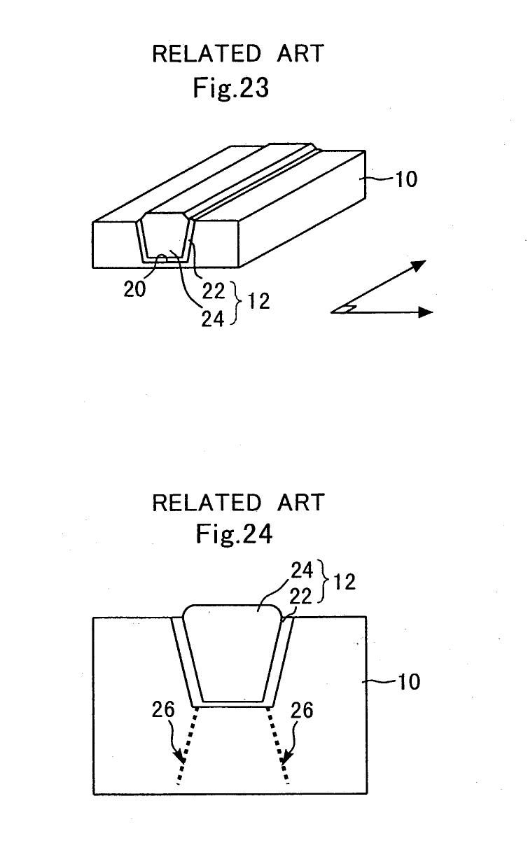

FIG. 8B shows an interior wall oxide film 22 formed by the thermal oxidation of the walls of a trench 20 formed along the cleavage face of a silicon crystal (refer to FIGS. 18 to 24). When the walls of the trench 20 formed along the cleavage face is subjected to a thermal oxidation process, the outward oxide growth tends to be greater than the inward oxide growth. Therefore, in order to round the edge of the trench 20 satisfactorily, it is necessary to impart a great thickness to the side wall of the interior wall oxide film 22. More concretely, the thickness of the interior wall oxide film must be at least about 300 Å when the inclination angle of the side walls of the trench 20 is 60°, and must be at least about 1200 Å when the inclination angle of the side walls of the trench 20 is 90°.

FIG. 8C shows the interior wall oxide film 38 formed on the side wall of the trench 36 by the semiconductor device manufacturing method in this embodiment. When crystal faces different from the cleavage face of the silicon crystal appear in the side walls of the trench 36, a large inward oxide growth is formed during the thermal oxidation. Therefore, this embodiment is capable of forming a large round edge 40 while limiting the thickness of the interior wall oxide film 38 to a value in the range of 150 Å to 800 Å.

In some cases, a gate electrode of a transistor is formed on the substrate 30 after forming the isolation oxide film 32 so as to cross the isolation oxide film 32. In such a case, a part of the active region 34 underlying the gate electrode serves as a channel of the transistor. It is desirable, in view of stabilizing the operations of the transistor, that an electric field is generated so as to be uniformly exerted on the entire channel when a voltage is applied to the gate electrode.

If the part of the active region 34 forming the channel has a sharp edge on the boundary between the active region 34 and the isolation oxide film 32, the electric field tends to concentrate in the edge of the channel and thereby the operation of the transistor is unstabilized. Therefore, it is effective in ensuring the stable operation of the transistor to form an appropriate round edge 40 at the edge of the active region 34.

It is effective in raising the level of integration of the semiconductor device to reduce the width of the isolation oxide film 32. The thickness of the interior wall oxide film 38 coating the side walls must be controlled to fill up the trench 36 properly with the filling oxide film 24 while reducing the width of the isolation oxide film 32 by a sufficient degree.

As mentioned above, the semiconductor device manufacturing method in this embodiment is capable of properly controlling the thickness of the interior wall oxide film 38 formed on the side walls and of rounding the rim of the active region 34 in the proper round edge 40. Accordingly, the semiconductor device manufacturing method in this embodiment is capable of manufacturing a semiconductor device having a high level of integration together with stable operation characteristics.

When the thickness of the interior wall oxide film 38 coating the side walls is controlled, stress that may be induced in the corners of the trench 36, i.e., in the boundaries of the bottom wall and the side walls of the trench 36 during the thermal oxidation process in which the corners of the trench 36 are oxidized from both sides of the side wall and the bottom wall of the trench 36 is reduced. The semiconductor device of this embodiment is, also in this respect, advantageous in preventing the development of crystal defects of the substrate 30.

### Second Embodiment

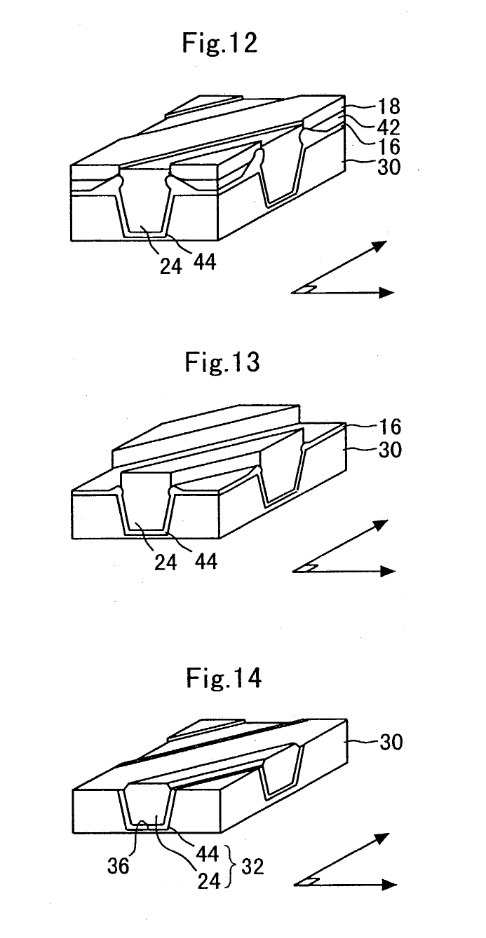

A second embodiment of the present invention will be described hereinafter with reference to FIG. 1 together with FIGS. 9 to 14.

The semiconductor device in the second embodiment, similarly to that in the first embodiment, includes a substrate 30 provided with an isolation oxide film 32 extending at an angle in the range of 45°±10° to the direction of the cleavage plane of the substrate 30 (see the drawings). A semiconductor device manufacturing method in this embodiment forms in a forming process of an isolation oxide film 32, a silicon oxide film 16, a polysilicon buffer layer 42 and a silicon nitride film 18 in that order so that the polysilicon buffer layer 42 is sandwiched between the silicon oxide film 16 and the silicon nitride film 18, and then executes a thermal oxidation process for forming an interior wall oxide film.

A method of forming the isolation oxide film 32 included in the semiconductor device in this embodiment will be described with reference to FIGS. 9 to 14.

FIG. 9 and FIGS. 11 to 14 are perspective views of a part surrounded by broken lines in FIG. 1 taken in the direction of the arrow B in FIG. 1.

When forming the isolation oxide film 32, the silicon oxide film 16, the polysilicon buffer layer 42 and the silicon nitride film 18 are formed in that order on the substrate 10. Then, the same photolithography process and the same etching process as those employed in the first embodiment are carried out to form trenches 36 (see FIG. 9). The trench 36 is, similarly to that of the first embodiment, formed so as to be inclined to the cleavage plane of the substrate 30.

Then, a thermal oxidation process is carried out to form an interior wall oxide film 44 so as to coat the walls of the trench 36.

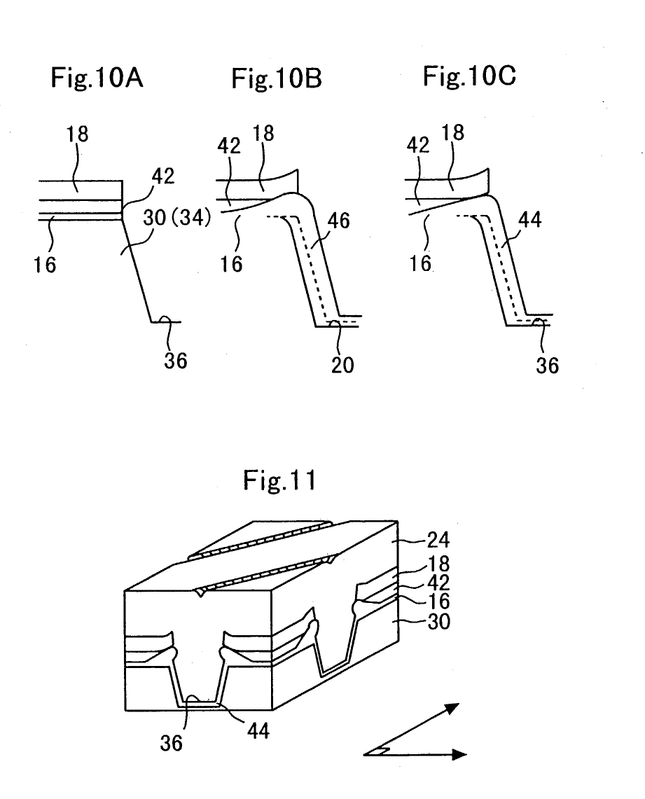

FIGS. 10A to 10C are views of assistance in explaining the features of the interior wall oxide film 44 formed by the semiconductor device manufacturing method in this embodiment. FIG. 10A is a sectional view of a part of the substrate 30 including the trench 36 before thermal oxidation. One of the purposes of the interior wall oxide film is the suppression of inverse channel effect in a transistor formed on the substrate 30. More concretely, one of the purposes of the interior wall oxide film is the prevention of formation of recesses in the edges of the isolation oxide film 32 (boundaries between the active regions 34 and the isolation oxide film 32). Therefore, a thermal oxidation process for forming the interior wall oxide film must secure an oxide layer of a sufficient thickness in an upper end part of the interior wall oxide film; that is, the thermal oxidation process must form the interior wall oxide film so that upper end parts of the interior wall oxide film bulges sufficiently on the upper edges of the trench 36.

FIG. 10B is a sectional view of an interior wall oxide film 46 (hereinafter referred to as a “comparative oxide film 46”) formed by the thermal oxidation of the walls of a trench 20 formed along the cleavage face of a silicon crystal. Since the polysilicon buffer layer 42 is readily oxidized, the polysilicon buffer layer 42 is oxidized rapidly, and a sufficient bulge is formed in an upper end part of the comparative oxide film 46 in an early stage after the start of thermal oxidation. Thus, the thickness of the comparative oxide film 46 coating the side walls can more properly be controlled and a necessary bulge can more easily be formed in the comparative oxide film 46 when the polysilicon buffer layer 42 is formed between the silicon oxide film 16 and the silicon nitride film 18 than when the silicon nitride film 18 is formed directly over the silicon oxide film 16.

FIG. 10C shows the interior wall oxide film 44 formed on the walls of the trench 36 by the semiconductor device manufacturing method in this embodiment. When the trench 36 in which crystal faces other than the cleavage face are exposed is thermal oxidized, the trench 36 is oxidized at a rate lower than a rate which is obtained when the trench 20 in which cleavage faces are exposed is thermal oxidized. Therefore, the semiconductor device manufacturing method in this embodiment is capable of forming the interior wall oxide film 46 having a film thickness of side walls smaller than that of the comparative oxide film 46 and hence the manufacturing method in this embodiment is capable of manufacturing the semiconductor device in a structure suitable for raising the level of integration.

The semiconductor device manufacturing method in this embodiment produces, in forming the interior wall oxide film 44, a degree of oxidation in the polysilicon buffer layer 44 smaller than that will be produced, in forming the comparative oxide film 46 (FIG. 10B), in the polysilicon buffer layer 44; that is, the semiconductor device manufacturing method in this embodiment is capable of forming the interior wall oxide film 44 so that a distortion caused in the silicon nitride film 18 is smaller than that will be caused in the silicon nitride film 18 when forming the comparative oxide film 46.

When forming the interior wall oxide film 44 or the comparative oxide film 46, a stress proportional to the distortion of the silicon nitride film 18 is induced in the active region 34 of the substrate 30. Therefore, it is desirable that the distortion of the silicon nitride film 18 is small in order to reduce the stress induced in the active region 34. In that respect, the semiconductor device manufacturing method in this embodiment is superior to the semiconductor device manufacturing method which forms the comparative oxide film 46 by subjecting the walls of the trench 20 in which the cleavage faces are exposed to a thermal oxidation process.

After the formation of the interior wall oxide film 44 by the foregoing method, the isolation oxide film 32 is completed by the same processes as those employed in the first embodiment (see FIGS. 11 to 14).

### Third Embodiment

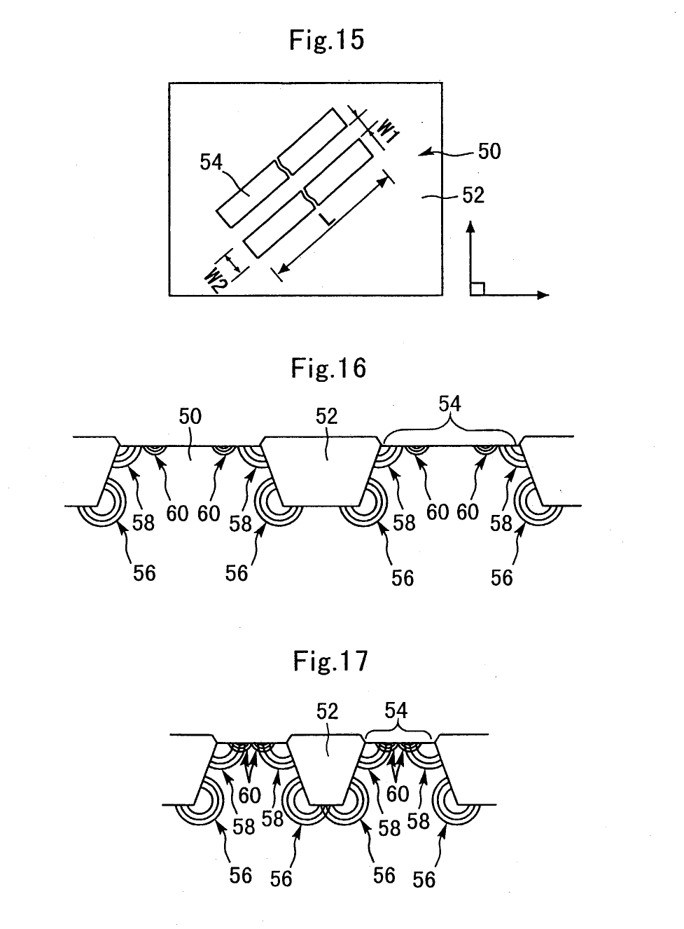

A third embodiment according to the present invention will be described hereinafter with reference to FIGS. 15 to 17.

FIG. 15 is a plan view of a substrate 50 included in a semiconductor device in the third embodiment, in which two arrows running perpendicular to each other indicate the direction of the cleavage plane of the substrate 50.

Memory cells of a flash memory are manufactured on the substrate 50. An isolation oxide film 52 having a region of a width W1 and a length L is formed on a surface of the substrate 50. Active regions 54 of a width W2 and a length L are formed on the substrate 50 and are isolated from each other by the isolation oxide film 52.

In this embodiment, the isolation oxide film 52 is formed so as to extend at an angle in the range of 45°±10° to the cleavage face of a silicon crystal in a part having the isolation width W1 and the isolation length L meeting conditions expressed by: 0<W1≦0.5 μm and 10 μm<L. The isolation oxide film 52 is formed so as to extend at an angle in the range of 45°±10° to the cleavage face of a silicon crystal also when the width W2 and the length L of the active region 54 provided adjacent thereto meet conditions expressed by: 0<W2≦0.8 μm and 10 μm<L.

FIG. 16 is a view of assistance in explaining parts in which stress is induced when forming the isolation oxide film 52 on the substrate 50 by a trench isolation technique. As shown in FIG. 16, stress is induced in (1) the corners 56 of trenches, (2) boundaries 58 between the active regions 54 and the trenches and (3) inner parts 60 of the active regions 54, when in a process for forming the isolation oxide film 52.

Namely, (1) in the corners 56 of the trench, stress is induced due to the difference of oxidation direction between the side walls and the bottom wall when forming an interior wall oxide film on the walls of the trench. (2) In the boundaries 58, stress is induced due to the difference of oxidation direction which is generated by a simultaneous inducement of lateral oxidation and oxidation along the side wall of the trench during the formation of the interior wall oxide film (i.e., during the formation of the round edges). (3) In the inner parts 60, stress is further induced due to the distortion of the silicon nitride film when forming the interior wall oxide film.

As shown in FIG. 16, the stresses induced respectively in the opposite corners 56 of the isolation oxide film 52 do not affect each other if the isolation width W1 is sufficiently secured. Similarly, stresses induced respectively in the boundaries 58 and the inner parts 60 do not affect each other when the width W2 of the active region 54 is sufficiently secured. Therefore, crystal defects are hardly caused by those stresses when the respective widths of the isolation oxide film 52 and the active region 54 are sufficiently secured.

FIG. 17 shows stresses induced when the width W1 of the isolation oxide film 52 is 0.5 μm or below and the width W2 of the active region 54 is 0.8 μm or below. As shown in FIG. 17, when the width W1 of the isolation oxide film 52 is as narrow as 0.5 μm or below, the stresses induced respectively in the opposite corners 56 of the isolation oxide film 52 affect each other. Similarly, the stresses induced respectively in the boundaries 58 and the inner parts 60 affect each other when the width W2 of the active region 54 is as small as 0.8 μm or below. Consequently, crystal defects are apt to be caused so as to extend in the direction in which the trench is extended when the isolation width W1 and the width W2 of the active region are satisfactorily narrow and the length L is 10 μm or above.

As mentioned above, the semiconductor device in this embodiment has the substrate 50 provided thereon with the isolation oxide film 52 meeting conditions expressed by 0<W1≦0.5 μm and 10 μm<L, and active regions 54 meeting conditions expressed by 0<W2≦0.8 μm and 10 μm<L. The semiconductor device manufacturing method in this embodiment carries out an oxidation process after the isolation oxide film 52 has been formed on the substrate 50 so that the degree of oxidation is resulted in 400 Å (10% of the isolation width W1 and 5% of the width W2 of the active region) or above. Thus, the semiconductor device in this embodiment is manufactured under process conditions which tend to cause crystal defects extending along the isolation oxide film 52.

However, as mentioned above, the isolation oxide film 52 in which crystal defects are apt to be caused is formed so as to be oblique to the cleavage plane of the substrate 50 in this embodiment. When the isolation oxide film 52 is formed obliquely to the cleavage plane, a high stress withstand ability with respect to a direction along the isolation oxide film 52 can be given to the substrate 50. Consequently, the structure of this embodiment is capable of forming the isolation oxide film 52 and the active regions 54 in minute dimensions and of effectively preventing causing crystal defects.

In the foregoing embodiment, the isolation oxide film is extended obliquely to the cleavage face of the silicon crystal in a part in which both the isolation oxide film 52 meeting 0<W1≦0.5 μm and the active region 54 meeting 0<W2≦0.8 μm are formed. However, the present invention is not limited to the embodiment. The direction of the isolation oxide film may be inclined to the cleavage face when the isolation width W1 meets 0<W1≦0.5 μm or the width W2 of the active region meets 0<W2≦0.8 μm.

Although only the isolation oxide film 52 of the width W1 meeting 0<W1≦0.5 μm and the active regions 54 of the width W2 meeting 0<W2≦0.8 μm are formed on the substrate 50 in the foregoing embodiment, an isolation oxide film of a width greater than W1 and active regions of a width greater than W2 may be formed in addition to the isolation oxide film 52 and the active regions 54. In such a case, the isolation oxide film may be formed in parallel to or perpendicularly to the cleavage plane in the part in which the wider isolation oxide film and the wider active regions are formed. Such a structure provides additional advantages of forming the isolation oxide film along the cleavage plane including facilitating the analysis of crystal faces or dicing the substrate into chips.

The major benefits of the present invention described above are summarized as follows:

According to the first aspect of the present invention, the isolation oxide film is formed obliquely to the cleavage face of the silicon crystal and the interior wall oxide film of an appropriate thickness is formed as a part of the isolation oxide film. This construction prevents causing crystal defects in a substrate effectively, forms appropriate round edges in active regions, and realizes a state advantageous for stabilizing the operation of a semiconductor device.

According to the second aspect of the present invention, the isolation oxide film is formed obliquely to the cleavage plane in a part where the isolation width W1 is as narrow as to cause the mutual action of stresses induced in predetermined parts during the isolation oxide film forming process. Therefore, the present invention prevents causing crystal defects regardless of the mutual action of the stresses.

According to the third aspect of the present invention, the isolation oxide film is formed along the direction inclined to the cleavage plane, in a part where the isolation width W1 is narrow and the isolation length L is long, i.e., a part where stress concentration occurs in a wide range. This construction prevents causing crystal defects and enables the construction of a semiconductor device of a high level of integration.

According to the fourth aspect of the present invention, the isolation oxide film is formed along the direction inclined to the cleavage plane in a part where the width W2 of the active region is narrow enough to cause the mutual action of stresses in a predetermine part during the isolation oxide film forming process. Therefore, the present invention prevents causing crystal defects regardless of the mutual action of the stresses.

According to the fifth aspect of the present invention, the isolation oxide film is formed along the direction inclined to the cleavage plane in a part where the width W2 of the active region is narrow and the length L of the same is long, i.e., a part where stress concentration occurs in a wide range. This construction prevents the causation of crystal defects and enables the construction of a semiconductor device of a high level of integration.

According to the sixth aspect of the present invention, the isolation oxide film can be formed obliquely to the cleavage plane, the interior wall oxide film can be formed in the least necessary thickness and appropriate round edges can be formed in the edges of the active region. Thus, the present invention is capable of manufacturing a semiconductor device of a high level of integration having stable operating characteristics.

According to the seventh aspect of the present invention, the polysilicon buffer layer is sandwiched between the silicon oxide film and the silicon nitride film. Therefore, the thickness of the interior wall oxide film coating the side walls of the trench can be reduced and the formation of recesses in the boundaries between the active regions and the isolation oxide film can be prevented. Thus, the present invention is capable of manufacturing a semiconductor device of a high level of integration having stable operating characteristics.

Further, the present invention is not limited to these embodiments, but variations and modifications may be made without departing from the scope of the present invention.

The entire disclosure of Japanese Patent Application No. Hei 10-348510 filed on Dec. 8, 1998 including specification, claims, drawings and summary are incorporated herein by reference in its entirety.

What is claimed is

1. A semiconductor device comprising an isolation oxide film formed so that boundaries between the isolation oxide film and active regions extend in a direction at an angle in the range of 45°±10° to the cleavage plane of a silicon substrate;
wherein the isolation oxide film has an interior wall oxide film of a thickness in the range of 50 Å to 1000 Å covering side walls and bottom walls of trenches, and a filling oxide film filling up the trenches coated with the interior wall oxide film.

2. The semiconductor device according to claim 1, wherein the thickness of the interior wall oxide film is not smaller than 150 Å and less than 800 Å.

3. The semiconductor device according to claim 1, wherein the isolation oxide film formed along the direction inclined to the cleavage plane of the silicon substrate is formed in a part meeting a condition expressed by: 0<W1≦0.5 μm, where W1 is an isolation width.

4. The semiconductor device according to claim 2, wherein the isolation oxide film formed along the direction inclined to the cleavage plane of the silicon substrate is formed in a part meeting a condition expressed by: 0<W1≦0.5 μm, where W1 is an isolation width.

5. The semiconductor device according to claim 3, wherein the isolation oxide film formed along the direction inclined to the cleavage plane of the silicon substrate is formed in a part meeting conditions expressed by: 0<W1≦0.5 μm and 10 μm≦L, where W1 is isolation width and L is isolation length.

6. The semiconductor device according to claim 4, wherein the isolation oxide film formed along the direction inclined to the cleavage plane of the silicon substrate is formed in a part meeting conditions expressed by: 0<W1≦0.5 μm and 10 μm≦L, where W1 is isolation width and L is isolation length.

7. The semiconductor device according to claim 1, wherein the isolation oxide film formed along the direction inclined to the cleavage plane of the silicon substrate is formed in a part contiguous to an active region meeting a condition expressed by: 0<W2≦0.8 μm, where W2 is the width of the active region.

8. The semiconductor device according to claim 2, wherein the isolation oxide film formed along the direction inclined to the cleavage plane of the silicon substrate is formed in a part contiguous to an active region meeting a condition expressed by: 0<W2≦0.8 μm, where W2 is the width of the active region.

9. The semiconductor device according to claim 7, wherein the isolation oxide film formed along the direction inclined to the cleavage plate of the silicon substrate is formed in a part contiguous to an active region meeting conditions expressed by: 0<W2≦0.8 μm and 10 μm≦L, where W2 is the width of the active region and L is the length of the active region.

10. The semiconductor device according to claim 8, wherein the isolation oxide film formed along the direction inclined to the cleavage plate of the silicon substrate is formed in a part contiguous to an active region meeting conditions expressed by: 0<W2≦0.8 μm and 10 μm≦L, where W2 is the width of the active region and L is the length of the active region.

11. A method of manufacturing a semiconductor device, comprising the steps of:
forming a trench in a silicon substrate so that the boundary between an active region and the trench extends in a direction at an angle in the range of 45°±10° to the cleavage plane of the silicon substrate;
subjecting the silicon substrate to thermal oxidation to form an interior wall oxide film of a thickness in the range of 50 Å to 1000 Å on side walls of the trench; and
forming an isolation oxide film by filling up the trench defined by walls coated with the interior wall oxide film with a filling oxide film.

12. The method of manufacturing a semiconductor device according to claim 11, wherein the thermal oxidation is carried out so that the interior wall oxide film is formed in a thickness in the range of 150 Å to 800 Å.

13. The method of manufacturing a semiconductor device according to claim 11, further comprising the step of forming a silicon oxide film, a polysilicon buffer layer and a silicon nitride film in that order on the silicon substrate prior to forming the trench in the semiconductor substrate; wherein
the step of forming the trench includes a sub step of forming an opening corresponding to the trench through the silicon nitride film, the polysilicon buffer layer and the silicon oxide film.

14. The method of manufacturing a semiconductor device according to claim 12, further comprising the step of forming a silicon oxide film, a polysilicon buffer layer and a silicon nitride film in that order on the silicon substrate prior to forming the trench in the semiconductor substrate; wherein
the step of forming the trench includes a sub step of forming an opening corresponding to the trench through the silicon nitride film, the polysilicon buffer layer and the silicon oxide film.
